(19) United States
(12) Patent Application Publication
(10) Pub. No.: US 2008/0272451 A1
(43) Pub. Date: Nov. 6, 2008

(54) Image Sensor and Method of Manufacturing The Same

(76) Inventor: Chung Kyung Jung, Anyang-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/109,710

(22) Filed: Apr. 25, 2008

(30) Foreign Application Priority Data
May 3, 2007 (KR) 10-2007-0042906

(51) Int. Cl. H01L 31/0232; H01L 31/18

(52) U.S. Cl. 257/432; 438/69; 257/E31.127

(57) ABSTRACT

An image sensor and method of manufacturing the same are provided. The image sensor can include a semiconductor substrate having unit pixels; an interlayer dielectric layer formed on the semiconductor substrate and including metal interconnections; a first protective layer comprising an oxide layer formed on the interlayer dielectric layer; a second protective layer comprising an oxide-nitride layer formed on the first protective layer; and a microlens formed on the second protective layer.

### CROSS-REFERENCE TO RELATED APPLICATION

The present application claims the benefit under 35 U.S.C. §119 of Korean Patent Application No. 10-2007-0042906, filed May 3, 2007, which is hereby incorporated by reference in its entirety.

### BACKGROUND

In general, an image sensor is a semiconductor device for converting optical images into electric signals, and is classified into a charge coupled device (CCD) and a complementary metal oxide semiconductor (CMOS) image sensor.

The CMOS image sensor is a device employing a switching mode to sequentially detect an output of each unit pixel by means of MOS transistors using peripheral devices, such as a control circuit and a signal processing circuit. The MOS transistors are formed on a semiconductor substrate corresponding to the number of the unit pixels through a CMOS technology.

As the number of pixels of the CMOS sensor increases to mega-levels, the size of the pixel has been scaled-down. Since the size of the pixel has become reduced, the size of a microlens aligned on the pixel is limited, so that the focus length between the pixel and the microlens is also limited.

In the process of manufacturing the image sensor, a metal interconnection layer and a passivation layer are formed on the pixels through a BEOL (back end of line) process. Currently, a distance between the microlens and a photodiode has become increased, causing loss of incident light.

Therefore, restriction is required for the metal interconnection layer and the passivation layer that form a circuit on the pixels.

### BRIEF SUMMARY

Embodiments of the present invention provide an image sensor and a method of manufacturing the same, capable of shortening a focal length between a microlens and a photodiode to reduce loss of incident light and improving the light sensitivity and light receiving rate of the image sensor.

An image sensor according to an embodiment comprises: a semiconductor substrate including unit pixels; an interlayer dielectric layer formed on the semiconductor substrate and including metal interconnections; a first protective layer formed of an oxide layer on the interlayer dielectric layer; a second protective layer formed of an oxide-nitride layer on the first protective layer; and a microlens formed on the second protective layer.

A method of forming an image sensor according to an embodiment comprises: forming an interlayer dielectric layer including metal interconnections on a semiconductor substrate including unit pixels; forming a first protective layer including an oxide layer on the interlayer dielectric layer; forming a second protective layer including an oxide-nitride layer on the first protective layer; and forming a microlens formed on the second protective layer.

### BRIEF DESCRIPTION OF THE DRAWINGS

FIGS. 1 to 6 are cross-sectional views showing a method of manufacturing an image sensor according to an embodiment.

### DETAILED DESCRIPTION

Hereinafter, an image sensor and a method of manufacturing the same will be described in detail with reference to accompanying drawings.

FIG. 6 is a cross-sectional view showing an image sensor according to an embodiment.

Referring to FIG. 6, an image sensor according to an embodiment can include a semiconductor substrate 10 having unit pixels 20, an interlayer dielectric layer 50 formed on the semiconductor substrate 10 and having metal interconnections 40, a first protective layer 61 formed on the interlayer dielectric layer 50, a second protective layer 70 formed on the first protective layer 61, and a microlens 90 formed on the second protective layer 70.

The first protective layer 61 can include an oxide layer. In a specific embodiment, the oxide layer can have a thickness of about 1000 Å to about 5000 Å.

The second protective layer 70 can include an oxide-nitride layer. In a specific embodiment, the oxide-nitride layer can have a thickness of about 10 Å to about 150 Å.

A color filter layer 80 and a planarization layer (not shown) can be formed on the second protective layer 70.

The first and second protective layers 61 and 70 have thin thicknesses, so that focal length between the unit pixel 20 and the microlens 90 can be reduced, thereby improving light sensitivity of the image sensor.

In addition, since the second protective layer 70 including the oxide-nitride layer is formed on the first protective layer 61, moisture of the first protective layer 61 can be reduced or removed, thereby inhibiting refraction of light incident into the microlens 90 and reducing crosstalk and noise.

Hereinafter, a method of manufacturing the image sensor according to certain embodiments of the present invention will be described.

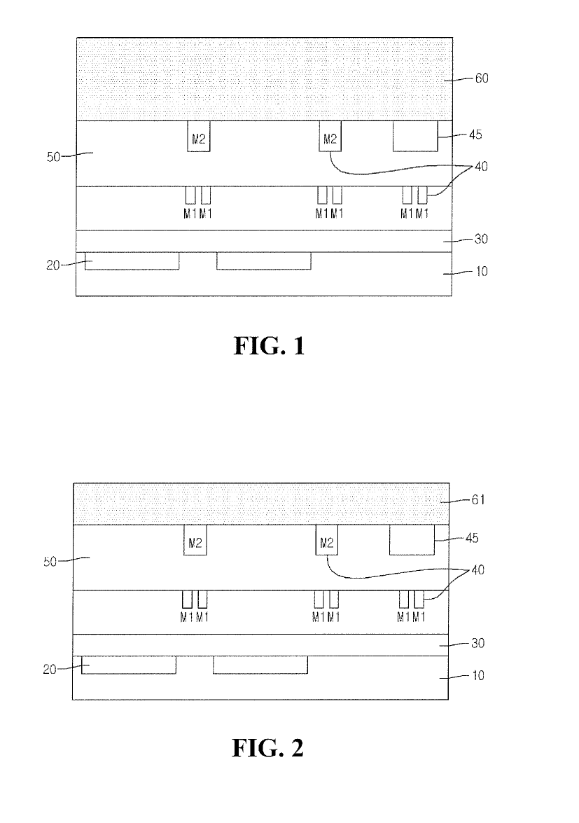

Referring to FIG. 1, an interlayer dielectric layer 50 including metal interconnections 40 can be formed on a semiconductor substrate 10.

Although not shown in the drawings, an isolation layer can be formed on the semiconductor substrate 10 to define an active area and a field area of the semiconductor substrate 10.

A unit pixel 20 can be formed on the active area of the semiconductor substrate 10. The unit pixel 20 can include, for example, a photodiode (not shown) for detecting incident light and a CMOS circuit (not shown) for processing electric charges generated from the photodiode.

Here, an area where the unit pixel 20 is formed is referred to as a pixel area and an area where a signal processing circuit is formed is referred to as a peripheral area.

A pre-metal dielectric layer 30 can be formed on the semiconductor substrate 10 having the pixel area and the peripheral area. In an embodiment, the pre-metal dielectric layer 30 includes a TEOS (tetraethyl orthosilicate) layer or a BPSG (boro-phospho silicate glass) layer.

A metal interconnection layer can be formed on the pre-metal dielectric layer 30. The metal interconnection layer includes metal interconnections 40, such as M1 and M2, formed in an interlayer dielectric layer 50.

The metal interconnection layer may be prepared in a multi-layer structure to connect power lines and signal lines with unit pixels and peripheral circuits. In other words, the interlayer dielectric layer 50 can have a multi-layer structure. Thus, a plurality of metal interconnections 40 can be formed through the interlayer dielectric layer 50. Although two metal layers (M1, M2) are illustrated in the figures, embodiments are not limited thereto.

The interlayer dielectric layer 50 can be an oxide layer. In certain embodiments, the interlayer dielectric layer can be a spin-on-glass (SOG) layer. The metal interconnections 40 can include various conductive materials including metal, alloy or silicide. For example, the metal interconnections can include aluminum, copper, cobalt, or tungsten.

In addition, the metal interconnections 40 can be intentionally designed to not interfere, or only minimally interfere, with light incident into the photodiode.

In a further embodiment, a pad 45 can be formed when the final metal interconnection (e.g., M2) of the metal interconnections 40 is formed.

Then, a protective layer 60 can be formed on the interlayer dielectric layer 50.

The protective layer 60 protects devices from humidity or scratch and is formed on the interlayer dielectric layer 50 including the final metal interconnection 40 and the pad 45.

The protective layer 60 can include an oxide layer. In one embodiment, the protective layer 60 can be obtained by depositing an oxide layer in the thickness of about 5000˜10000 Å. The oxide layer can be, for example, undoped silicate glass (USG) or TEOS.

Referring to FIG. 2, a predetermined thickness of the protective layer can be removed to form a first protective layer 61.

In order to form the first protective layer 61, the protective layer 60 can be etched and/or planarized through a CMP (Chemical Mechanical Polishing) process to remove a first thickness.

In one embodiment, the protective layer 60 can be subject to the CMP process in order to reduce the thickness of the first protective layer 61 to the range of about 1000˜5000 Å.

As the thickness of the first protective layer 61 becomes thinner, the focal length between the photodiode of the pixel area and a microlens, which is formed through a subsequent process, is reduced so that the light receiving rate and light sensitivity of the photodiode can be improved.

In one preferred embodiment, the protective layer 60 is etched such that the first protective layer 61 obtains a thickness of about 3000 Å.

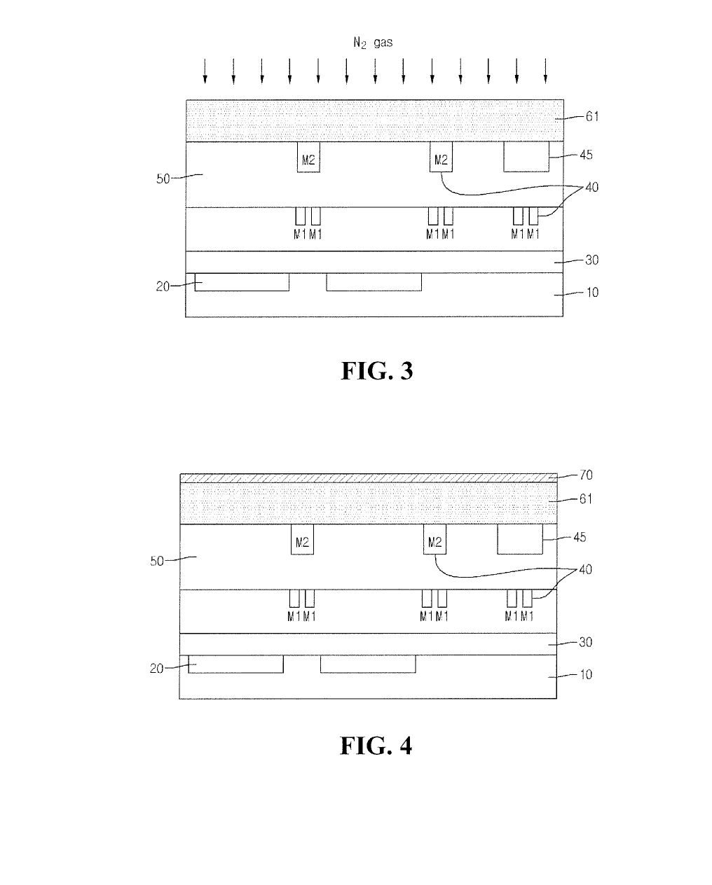

Referring to FIGS. 3 and 4, nitrogen gas (N₂ gas) can be supplied onto the first protective layer 61 to form a second protective layer 70 on the first protective layer 61.

Since the first protective layer 61 includes an oxide layer, the first protective layer 61 may include moisture. For this reason, the nitrogen gas is supplied onto the first protective layer 61. That is, if moisture exists between the first protective layer 61 and a microlens formed through a subsequent process, the refractive index changes, resulting in light being incident areas other than the photodiode and causing crosstalk and noise.

Accordingly, nitrogen gas can be supplied onto the first protective layer 61 to form the second protective layer 70 on the first protective layer 61. In an embodiment, the nitrogen gas can be supplied through a plasma deposition process.

In a specific embodiment, the semiconductor substrate 10 having the first protective layer 61 is loaded in a chamber used for the plasma deposition process. Then, nitrogen gas is supplied into the chamber with pressure of 10 to 500 mtorr and a flow rate of 10 to 500 seem to form the second protective layer 70 of the oxide-nitride layer on the first protective layer 61.

Thus, the second protective layer 70 having a thickness of about 10 Å to about 150 Å can be formed on the first protective layer 61 through the plasma deposition process.

Since the second protective layer 70 including the oxide-nitride layer is formed on the first protective layer 61 by performing the plasma deposition process using the nitrogen gas, the refractive index of light incident through the microlens can be inhibited from being changed even if the first protective layer 61 contained moisture.

According to an embodiment, the first protective layer 61 can have a thickness of about 3000 Å and the second protective layer 70 can have a thickness of about 10 Å to about 100 Å, which are smaller thicknesses than the thickness of a conventional protective layer. Therefore, the focal length between the microlens and the photodiode can be reduced, thereby improving the light receiving rate and light sensitivity of the image sensor.

In certain embodiments, the second protective layer 70 can be formed in the same process chamber used for forming the first protective layer 61, so that the manufacturing cost can be reduced.

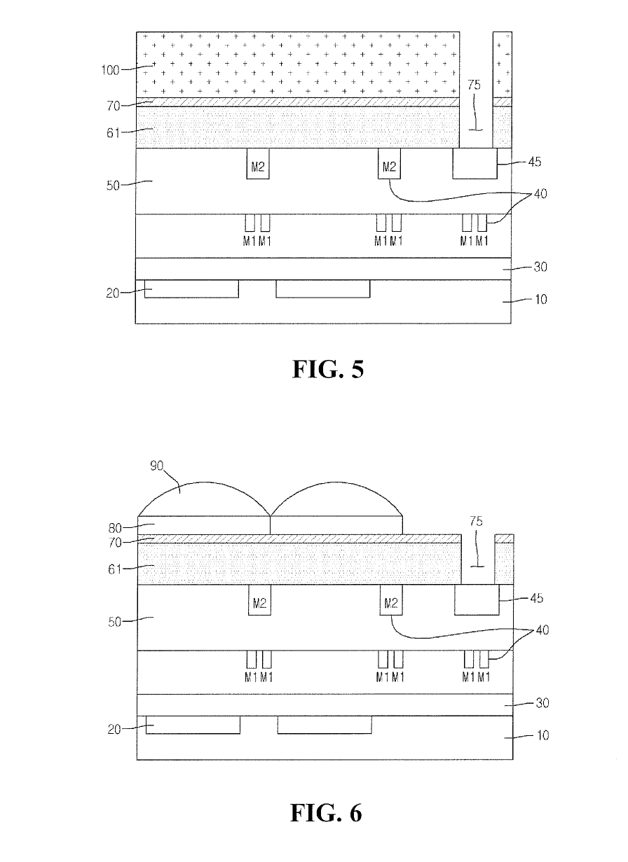

Referring to FIG. 5, an upper surface of the pad 45 can be exposed by using a pad mask 100 formed on the semiconductor substrate 10 including the second protective layer 70.

The pad mask 100 can be formed by coating and patterning photoresist on the semiconductor substrate 10 having the second protective layer 70. At this time, the upper surface of the second protective layer 70, which corresponds to a pad area, is exposed through a pad hole of the pad mask 100 and the remaining area of the second protective layer 70 is covered with the pad mask 100.

In this state, the first and second protective layers 61 and 70 are etched by using the pad mask 100 as an etch mask, thereby forming a pad open hole 75 for exposing the pad 45.

Then, the pad mask 100 is removed leaving the pad 45 exposed.

Referring to FIG. 6, a color filter layer 80 and a microlens 90 can be formed on the second protective layer 70.

The color filter layer 80 can include three color filters for realizing a color image. The color filters can be obtained by depositing dyed photoresist. Each unit pixel can include one color filter to separate a color from incident light. In many embodiments, the color filters include red, green and blue color filters, in which adjacent color filters may slightly overlap with each other while forming step difference therebetween.

Although not shown in the drawings, a planarization layer can be formed on the color filter layer 80. The microlens, which will be formed through a subsequent process, should be formed on a planar surface. To this end, the planarization layer can be formed on the color filter layer 80 to remove any step difference caused by the color filter layer 80.

Then, the microlens 90 having a dome-shape can be formed on the color filter layer 80 corresponding to, for example, each unit pixel 20.

Since the second protective layer 70 including the oxide-nitride layer is formed on the first protective layer 61 including the oxide layer having the thin thickness through the plasma deposition process, the focal length between the microlens 90 and the unit pixel 20 can be reduced without exerting an influence upon the refractive index of the microlens 90, so that light receiving rate and light sensitivity of the image sensor can be improved.

The image sensor and the method of manufacturing the same according to embodiments of the present invention can reduce the focal length between the microlens and the photodiode by reducing the thickness of the protective layer, so that loss of incident light can be reduced, thereby improving the light sensitivity and light receiving rate of the image sensor.

In addition, since the second protective layer is formed on the first protective layer through the plasma deposition process, moisture contained in the first protective layer can be removed, so that the refractive index of incident light is reduced and the thickness of the first protective layer can be reduced, thereby improving the light sensitivity of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a semiconductor substrate including unit pixels;
an interlayer dielectric layer on the semiconductor substrate and including metal interconnections;
a first protective layer on the interlayer dielectric layer, wherein the first protective layer comprises an oxide layer;
a second protective layer on the first protective layer, wherein the second protective layer comprises an oxide-nitride layer; and
a microlens on the second protective layer.

2. The image sensor according to claim 1, wherein the first protective layer has a thickness in a range of about 1000 Å to about 5000 Å.

3. The image sensor according to claim 1, wherein the second protective layer has a thickness in a range of about 10 Å to about 150 Å.

4. The image sensor according to claim 1, wherein the first protective layer is an undoped silicate glass (USG) layer.

5. The image sensor according to claim 1, wherein the first protective layer is a TEOS layer.

6. A method of forming an image sensor, comprising:
forming an interlayer dielectric layer including metal interconnections on a semiconductor substrate including unit pixels;
forming a first protective layer comprising an oxide layer on the interlayer dielectric layer;
forming a second protective layer comprising an oxide-nitride layer on the first protective layer; and
forming a microlens formed on the second protective layer.

7. The method according to claim 6, wherein forming the first protective layer comprises:
forming the oxide layer on the interlayer dielectric layer; and
etching the oxide layer to remove a first thickness.

8. The method according to claim 7, wherein forming the oxide layer comprises depositing the oxide layer to a thickness in a range of about 5000 Å to about 10,000 Å.

9. The method according to claim 7, wherein etching the oxide layer comprises performing chemical mechanical polishing.

10. The method according to claim 7, wherein after removing the first thickness, the oxide layer has a thickness in a range of about 1000 Å to about 5000 Å.

11. The method according to claim 6, wherein forming the second protective layer comprises forming the oxide-nitride layer using a portion of the first protective layer.

12. The method according to claim 6, wherein the oxide-nitride layer is formed to have a thickness in a range of about 10 Å to about 150 Å.

13. The method according to claim 6, wherein forming the second protective layer comprises performing a plasma process with respect to the first protective layer.

14. The method according to claim 13, wherein performing the plasma process comprises supplying nitrogen gas with a flow rate of 100 to 500 sccm and pressure of about 10 to 500 mtorr.

15. The method according to claim 6, wherein the first and second protective layers are formed in the same process chamber.

16. The method according to claim 6, wherein the first protective layer is a USG layer.

17. The method according to claim 6, wherein the first protective layer is a TEOS layer.
